(19) United States
(12) Patent Application Publication
(10) Pub. No.: US 2018/0204101 A1
(43) Pub. Date: Jul. 19, 2018

(54) PROTECTION SYSTEM FOR RADIO FREQUENCY SWITCHES

(71) Applicant: QUALCOMM Incorporated, San Diego, CA (US)

(72) Inventors: Maurice Adrianus DE JONGH, Nijmegen (NL); Jiri STULEMEIJER, Heerlen (NL); Perry Wyan LOU, Carlsbad, CA (US); Clint KEMERLING, Rancho Santa Fe, CA (US); David Loweth WINSLOW, San Diego, CA (US); Anton ARRIAGADA, San Marcos, CA (US)

(21) Appl. No.: 15/607,103

(22) Filed: May 26, 2017

Related U.S. Application Data
(60) Provisional application No. 62/446,340, filed on Jan. 13, 2017.
(60) Provisional application No. 62/448,836, filed on Jan. 20, 2017.

(51) Int. Cl. G06K 19/07; G06K 19/073; G06K 19/077; G08B 13/14; H03B 19/05; H01Q 1/22

(52) U.S. Cl. CPC G06K 19/0725; G06K 19/073; G06K 19/07309; H01Q 1/2225; G08B 13/1454; H03B 19/05; G06K 19/07773

(57) ABSTRACT

An antenna tuning circuit achieves robust performance in a closed loop antenna tuning system due to the addition of protection circuits. In one instance, a protection circuit to detect an overload condition based on a threshold value may be included in the antenna tuning circuit. The antenna tuning circuit also includes a protection state register coupled to the protection circuit to store one or more safe states of operation to which the circuit is restored in response to detecting the overload condition. The antenna tuning circuit also includes a bus interface coupled to the protection state register to transmit an indication of a state of operation of the circuit to an external tuning control device coupled to the circuit and to receive pre-defined protection actions from the external tuning control device in response to the indication of the state of operation.

### CROSS-REFERENCE TO RELATED APPLICATIONS

The present application claims the benefit of U.S. Provisional Patent Application No. 62/448,836, filed on Jan. 20, 2017, and titled “PROTECTION SYSTEM FOR RADIO FREQUENCY SWITCHES,” and U.S. Provisional Patent Application No. 62/446,340, filed on Jan. 13, 2017, and titled “PROTECTION SYSTEM FOR TUNING DEVICES,” the disclosures of which are expressly incorporated by reference herein in their entireties.

### TECHNICAL FIELD

The present disclosure generally relates to radio frequency (RF) switching. More specifically, aspects of the present disclosure relate to radio frequency tuning and a protection system for transistor based radio frequency switch stacks.

### BACKGROUND

In modern handheld devices for cellular communication systems (e.g. 3GPP) there is a desire to support multiple frequency bands (e.g., 3GPP LTE bands 1, 2, 3, 5, 7, 8, and 13). To support the multiple frequency bands, electronic switches (e.g., RF switches) may be used to achieve selection or switching to each of the multiple frequency bands. The electronic switches may be based on transistors, such as field-effect transistors (FETs). The FETs (e.g., multiple FETs in series) may be used for voltage handling of the RF switches. In RF applications such as mobile phones, which have high RF transmission output power, the RF voltage swing can be higher than the maximum voltage that one single FET can handle. Further, high power associated with transmitters challenges the voltage handling of the RF switches.

Radio frequency switches may be used for tuning antennas and for impedance matching. In the case of cellular antennas, multiple antennas support different wireless protocols or cellular communication systems such as 2G/3G/4G, near field communication (NFC), Wi-Fi®/Bluetooth®, GPS, and FM radio. The need for multiple antennas, coupled with reducing size and volumetric constraints, creates a challenging environment for wireless antenna systems. Thus, the space available for the antenna system is shrinking at a rapid rate.

As antennas are reshaped from their ideal and reused for multiple frequency bands and protocols, they lose efficiency. Some of this lost performance may be recovered with active antenna tuning systems (e.g., using the RF switches). A tuning system may use dynamic impedance/frequency/radiation pattern/efficiency tuning techniques to optimize antenna performance for both frequency of operation and environmental conditions (including user interactions with the phone or antenna, such as the user's hand grip partially covering the antenna).

### SUMMARY

In an aspect of the present disclosure, a circuit includes a protection circuit to detect an overload condition based on a threshold value. The circuit also includes a protection state register coupled to the protection circuit to store one or more safe states of operation to which the circuit is restored in response to detecting the overload condition. The circuit further includes a bus interface coupled to the protection state register to transmit an indication of a state of operation of the circuit to an external tuning control device coupled to the circuit and to receive pre-defined protection actions from the external tuning control device in response to the indication of the state of operation.

According to another aspect of the present disclosure, a circuit includes means for detecting an overload condition of an antenna tuning device on a threshold value. The circuit also includes a protection state register coupled to the overload condition detecting means to store one or more safe states of operation to which the circuit is restored in response to detecting the overload condition. The circuit further includes a bus interface coupled to the protection state register to transmit an indication of a state of operation of the circuit to an external tuning control device coupled to the circuit and to receive pre-defined protection actions from the external tuning control device in response to the indication of the state of operation.

Yet another aspect discloses a method for protecting a circuit includes detecting an overload condition. The method also includes adjusting an operation state of the circuit in response to detecting the overload condition to restore the circuit to a safe operation state based on at least one safe operation state stored in a protection state register of the circuit.

Additional features and advantages of the disclosure will be described below. It should be appreciated by those skilled in the art that this disclosure may be readily utilized as a basis for modifying or designing other structures for carrying out the same purposes of the present disclosure. It should also be realized by those skilled in the art that such equivalent constructions do not depart from the teachings of the disclosure as set forth in the appended claims. The novel features, which are believed to be characteristic of the disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 illustrates a wireless device in accordance with an exemplary aspect of the present disclosure.

FIG. 2 illustrates an example of a closed-loop antenna tuning device or protection system with multiple antennas according to aspects of the present disclosure.

FIG. 3 illustrates a switch stack according to aspects of the present disclosure.

FIG. 4 shows a schematic diagram of an exemplary design of an impedance matching circuit.

FIG. 5 shows a schematic diagram of an exemplary design of an aperture tuning circuit.

FIG. 6 illustrates an example of a closed loop tuning system.

FIG. 7 illustrates a block schematic of an example tuning device.

FIG. 8 illustrates an example of a closed loop tuning system according to aspects of the present disclosure.

FIG. 9 illustrates a block schematic of an example tuning device according to aspects of the present disclosure.

FIG. 10 depicts a simplified flowchart of a method for protecting a switch circuit or an antenna tuning circuit according to one aspect of the disclosure.

FIG. 11 depicts another simplified flowchart of a method for protecting an antenna tuning circuit or switch circuit according to one aspect of the disclosure.

FIG. 12 is a block diagram showing an exemplary wireless communication system in which a configuration of the disclosure may be advantageously employed.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. It will be apparent to those skilled in the art, however, that these concepts may be practiced without these specific details. In some instances, well-known structures and components are shown in block diagram form in order to avoid obscuring such concepts. As described herein, the use of the term “and/or” is intended to represent an “inclusive OR” and the use of the term “or” is intended to represent an “exclusive OR”.

Antenna tuning systems/circuits and methods include impedance tuning, antenna switch diversity, and aperture tuning. In general, impedance tuners or impedance matching circuits correct antenna input impedance. For example, impedance matching or tuning (e.g., fine tuning) may be employed for fine radio frequency (RF) tuning over a limited tuning range. Impedance matching optimizes or improves power transfer from a transmission line into the antenna terminals by matching input impedance and output impedance. Impedance matching tunes the antenna to the entire system, creating a tuned matching network that is added to the antenna input. Impedance matching provides improvement in total radiated power (TRP) and total isotropic sensitivity (TIS) metrics.

Aperture tuning (e.g., course tuning) is incorporated into the antenna design to enable a wider frequency range. In general, aperture tuning within an antenna changes frequency and efficiency (e.g., radiation pattern) of the antenna. With aperture tuning, the tunable component is added to the antenna structure or coupled to the antenna structure. For example, an electrical length of an antenna element is dynamically adjusted to shift its resonance to the desired frequency band of operation. Frequency band switching could achieve higher levels of performance compared with input tuning, as the actual radiating element is being tuned. Aperture tuning (also referred to as coarse tuning) optimizes or improves radiation efficiency from the antenna terminals into free space. Aperture tuning also enables concurrent tuning of low frequency band (LB)/medium frequency band (MB) or LB/MB/high frequency band (HB). Also, aperture tuning optimizes or improves insertion loss, isolation, and rejection levels. For example, tuning is achieved by loading with a digitally tunable capacitor (DTC) or by using a tunable control/shorting switch.

Aspects of the present disclosure offer robust performance in closed loop antenna tuning systems due to the addition of protection circuits. For example, the protection circuits may be included in a tuning circuit (e.g., an antenna tuning circuit). The tuning circuit may be a silicon-on-insulator radio frequency circuit including at least one field effect transistor. Examples of an antenna tuning circuit include an antenna switch diversity circuit, radio frequency switches in a radio frequency front end module, a detuning circuit, an antenna switch diversity circuit and/or an aperture tuning circuit.

A protection system or protection circuits of the protection system for the antenna tuning circuit may be formed with switch circuits. The switch circuits may include radio frequency switches based on field effect transistors that are included in a user equipment or cellular device. For example, the protection circuit can also be added to antenna switch diversity (AsDiv) switches and switches of a radio frequency front end (e.g., front-end receive/transmit (Rx/Tx) modules). The tuning circuit may also be based on radio frequency switches made with field effect transistors. The protection circuit is desirable for future technology scaling towards smaller technology nodes where the voltage for each field effect transistor drops and the desire for rugged protection becomes more important. The switch protection system may also use an AsDiv switch to ‘route’ the signal to another antenna (to avoid circuit overload) or alternatively reduce output power of a power amplifier (e.g., when AsDiv is not available). The protection circuit allows for “under-design” of maximum voltage, and therefore may reduce costs.

The protection circuit may detect an overvoltage condition or undesirable conditions such as those that may occur during hot-switching. For example, transmit (Tx) signal levels may become too high, causing the switches to latch to an undesirable state. Hot-switching changes state to improve matching conditions, includes turning ON/OFF switches when a radio frequency power is present. Consequences of switches latching during hot-switching include high harmonics, power loss, and undesirable switch conditions.

In one instance, detecting the overvoltage condition includes comparing a direct current (DC) from a charge pump to a current threshold and determining an overvoltage condition when the direct current is greater than the current threshold. The charge pumps provide voltage levels for turning the switches ON or OFF. In another instance, a frequency of a control loop (e.g., regulated charge pump output voltage control loop) can be detected, instead of the direct current, or charge pump control voltage (of a feedback loop).

Although an overvoltage condition is described, the aspects of the disclosure may also be implemented with other conditions (e.g., temperature conditions). For example, other overload conditions include overcurrent conditions or saturation leading to poor harmonic performance or high power dissipation conditions. In other aspects, the external tuning control device detects the overload condition by detecting a second or third harmonic from non-linear signal detection. For example, a feedback receiver (FBRX) (not shown) external to the matching circuit can measure unwanted harmonics in other frequency bands. When these unwanted harmonics reach or are above a threshold value indicating an undesirable situation, a protection state is triggered.

A protection state register may be coupled to the protection circuit to store one or more safe states of operation of the antenna tuning circuit. The antenna tuning circuit is immediately placed in one of the safe states of operation in response to detecting an overvoltage condition. In one aspect of the disclosure, a bus interface is coupled to the protection state register to transmit an indication of a state of operation of the antenna tuning circuit to an external tuning control device (e.g., a modem or controller/processor). The external tuning control device includes one or more state registers to store one or more tuning states for the circuit, one or more protection states of the circuit and pre-defined protection actions. The external tuning control device may be coupled to the antenna tuning circuit. The antenna tuning circuit receives pre-defined protection actions from the external tuning control device in response to an indication that the antenna tuning circuit is operating in a safe state.

Some of the pre-defined protection actions are looped back or submitted to the modem and/or other parts of a transceiver to achieve better system performance. Better system performance may be achieved by lowering power transmitted by a power amplifier, or selecting a different antenna in accordance with antenna switch diversity (AsDiv). For example, antenna switch diversity may be achieved by changing signals from one antenna to the other, if transmission/reception on the other antenna is better than the first antenna.

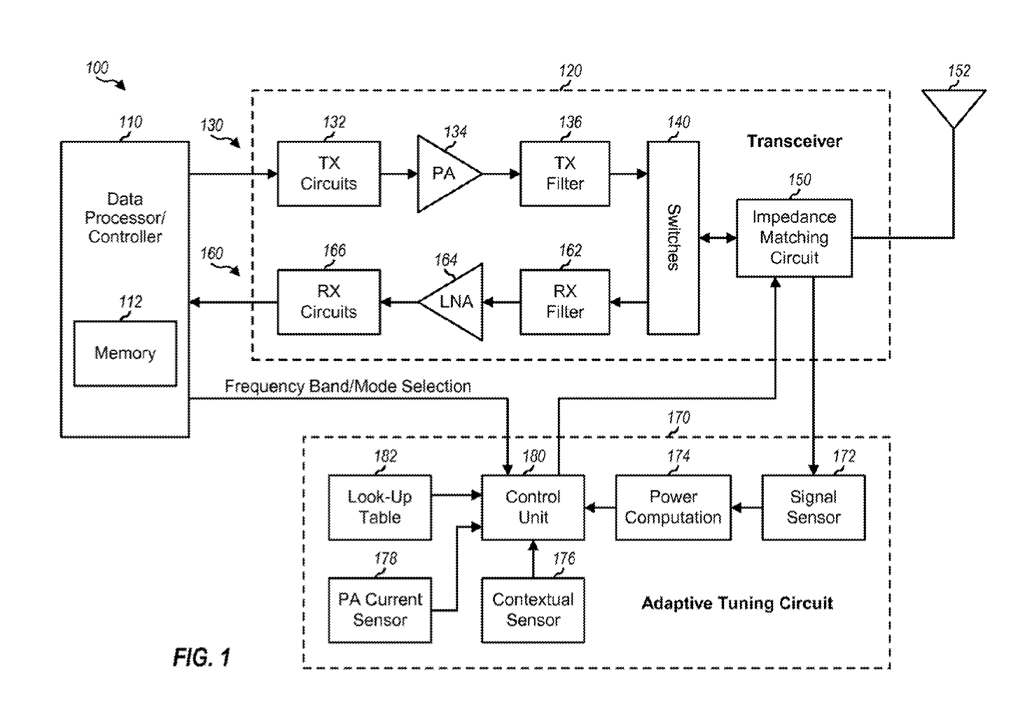

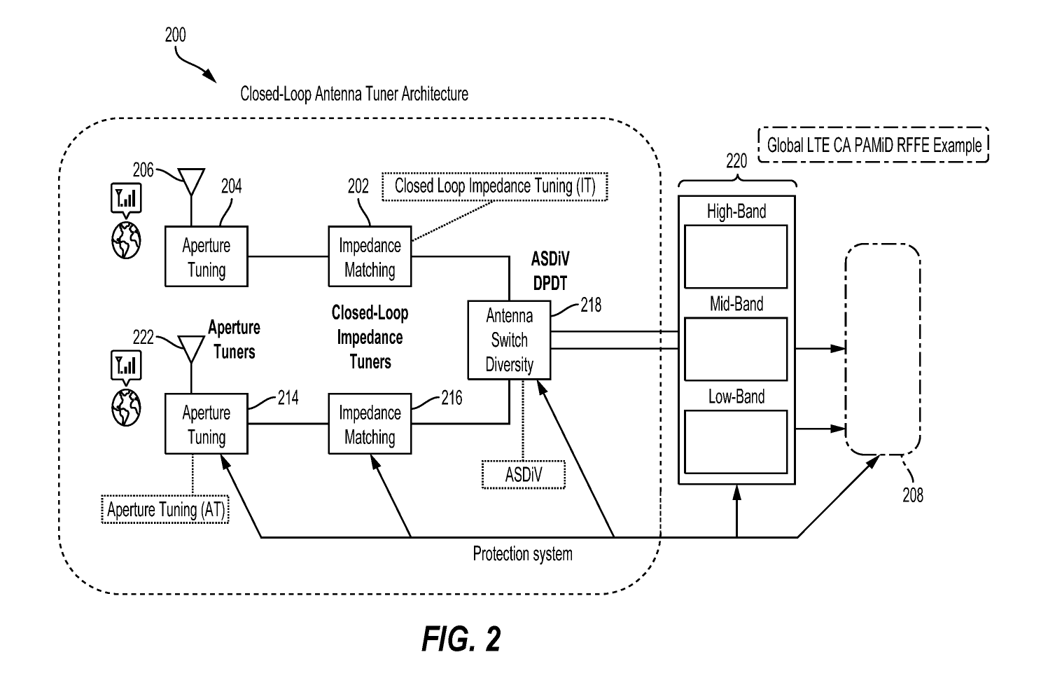

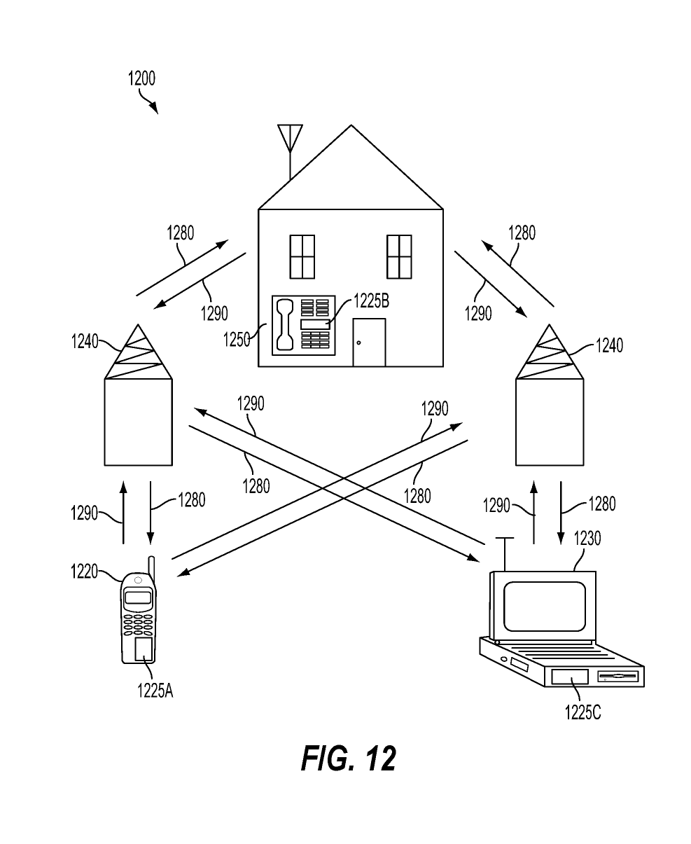

The concepts of the present disclosure may be implemented in a wireless device of FIG. 1 and the wireless communication systems of FIGS. 2 and 12.

FIG. 1 illustrates a wireless device 100 in accordance with an exemplary aspect of the present disclosure. FIG. 1 and the corresponding description is illustrated in the context of a wireless device, generally, for the purpose of illustration. Nevertheless, it will be understood that these principles of the disclosure are not necessarily limited to the general wireless device, and can also be directed to silicon-on-insulator (SOI) switches, antenna switch diversity, aperture tuners, impedance tuners (e.g., impedance matching), front end switches, etc.

The wireless device 100 includes a data processor/controller 110, a transceiver 120, an adaptive tuning circuit 170, and an antenna 152. In some implementations, the adaptive tuning circuit is included in the data processor/controller 110. Although only one adaptive tuning circuit 170 is illustrated, the present disclosure is not limited to one adaptive tuning circuit of the wireless device 100. For example, the wireless device 100 may include multiple adaptive tuning circuits (tuner/switch blocks) where each adaptive tuning circuit includes a protection circuit according to aspects of the present disclosure. The transceiver 120 includes a transmitter 130 and a receiver 160 that support bi-directional wireless communication. The wireless device 100 may support 5G, Long Term Evolution (LTE), Code Division Multiple Access (CDMA) lx or cdma2000, Evolution-Data Optimized (EVDO), Time Division Synchronous CDMA (TD-SCDMA), Wideband CDMA (WCDMA), or some other version of CDMA, Global System for Mobile Communications (GSM), IEEE 802.11 system (wireless local area network (WLAN)), etc.

In the transmit path, the data processor 110 processes (e.g., encodes and modulates) data to be transmitted and provides an analog output signal to the transmitter 130. Within the transmitter 130, the transmit (TX) circuits 132 amplify, filter, and upconvert the analog output signal from baseband to RF and provide a modulated signal. The TX circuits 132 may include amplifiers, filters, mixers, an oscillator, a local oscillator (LO) generator, a phase locked loop (PLL), etc. A power amplifier (PA) 134 receives and amplifies the modulated signal and provides an amplified RF signal having the proper output power level. A TX filter 136 filters the amplified RF signal to pass signal components in a transmit band and attenuate signal components in a receive band. The TX filter 136 provides an output RF signal, which is routed through switches 140 and a tuning circuit (e.g., an impedance matching circuit 150 or aperture tuning circuit) and transmitted via the antenna 152. The impedance matching circuit 150 performs impedance matching for the antenna 152 and is also referred to as an antenna tuning circuit, a tunable matching circuit, etc.

In the receive path, the antenna 152 receives signals from base stations and/or other transmitter stations and provides a received RF signal, which is routed through the impedance matching circuit 150 and the switches 140 and provided to the receiver 160. Within the receiver 160, a receive (RX) filter 162 filters the received RF signal to pass signal components in the receive band and attenuate signal components in the transmit band. An LNA 164 amplifies a filtered RF signal from the RX filter 162 and provides an input RF signal. RX circuits 166 amplify, filter, and downconvert the input RF signal from RF to baseband and provide an analog input signal to the data processor 110. The RX circuits 166 may include amplifiers, filters, mixers, an oscillator, an LO generator, a PLL, etc.

The adaptive tuning circuit 170 tunes or adjusts the impedance matching circuit 150 such that good performance can be achieved for data transmission and reception. Within the adaptive tuning circuit 170, a sensor 172 receives input signals from the impedance matching circuit 150 and measures the voltage, current, power, and/or other characteristics of the input signals. In some implementations, a computation unit 174 receives the measurements or interrupts representative of a condition of the impedance matching circuit from the sensor/interrupt interface (or bus interface interrupt) 172 and determines the delivered power and/or the impedance of the load observed by the impedance matching circuit 150, which is the antenna 152 in FIG. 1. In other implementations, the control unit receives interrupts or indications representative of a condition or state of the impedance matching circuit 150 directly from the impedance matching circuit 150. A control unit 180 receives the delivered power and/or impedance from the computation unit 174. The control unit 180 may also receive the outputs of contextual sensors 176, PA current from a PA current sensor 178, and a control signal indicative of a selected frequency band/channel and/or a selected mode from the processor 110. The control unit 180 may also receive performance characterizations for different possible settings of the impedance matching circuit 150 from a look-up table 182. The control unit 180 generates a control signal to tune the impedance matching circuit 150 to achieve good performance, e.g., to obtain higher delivered power to the load.

In some aspects, the adaptive tuning circuit 170 may also include fewer, different and/or other sensors. The computation unit 174 may be separate from the control unit 180 (as shown in FIG. 1) or may be part of the control unit 180. All or part of the adaptive tuning circuit 170 may be implemented digitally. For example, the computation unit 174 and the control unit 180 may be implemented by the data processor/controller 110. The look-up table 182 may be stored in the memory 112 or some other memory.

All or a portion of the transceiver 120 and the adaptive tuning circuit 170 may be implemented on one or more analog integrated circuits (ICs), RF ICs (RFICs), mixed-signal ICs, etc. The power amplifier 134 and possibly other circuits may be implemented on a separate IC or module. The impedance matching circuit 150 and possibly other circuits may also be implemented on a separate IC or module.

The data processor/controller 110 may perform various functions for the wireless device 100. For example, the data processor 110 may perform processing for data being transmitted via the transmitter 130 and received via the receiver 160. The controller 110 may control the operation of the TX circuits 132, the RX circuits 166, the switches 140, and/or the adaptive tuning circuit 170. The memory 112 may store program codes and data for the data processor/controller 110. The memory 112 may be internal to the data processor/controller 110 (as shown in FIG. 1) or external to the data processor/controller 110 (not shown in FIG. 1). The data processor/controller 110 may be implemented on one or more application specific integrated circuits (ASICs) and/or other ICs.

FIG. 2 illustrates an example of a closed-loop antenna tuning device or protection system 200 with multiple antennas according to aspects of the present disclosure. The protection system includes impedance matching circuits 202 and 216, aperture tuning circuits 204 and 214, an antenna switch diversity device 218 (e.g., switch), a multi-band front end module 220 and a controller 208 (e.g., modem and corresponding control algorithm). In one aspect of the disclosure, the modem 208 may act in response to an overvoltage condition or hot-switching condition at the aperture tuning circuit 204 and/or the impedance matching circuit 202. For example, the modem may cause a selection of a different antenna 222 from the antenna 206 associated with the aperture tuning circuit 204 and/or the impedance matching circuit 202. The antenna selection is in accordance with antenna switch diversity (AsDIV).

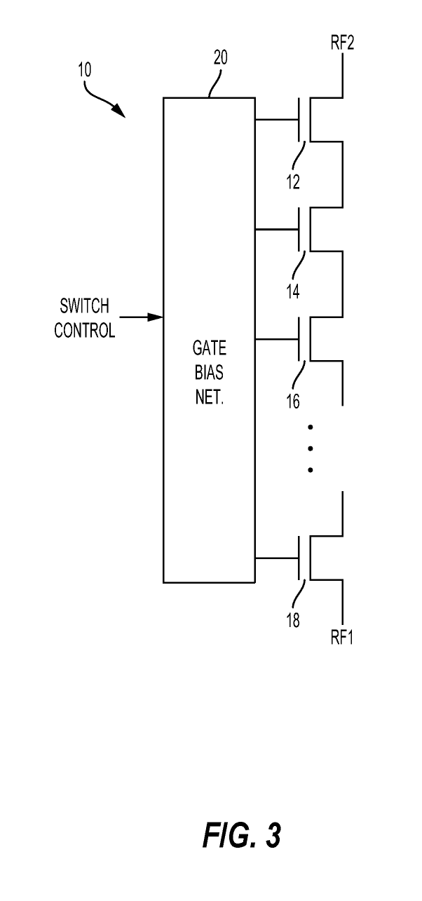

FIG. 3 illustrates a switch stack according to aspects of the present disclosure. Electronic switches are commonly based on transistors, such as field-effect transistors (FETs). In radio frequency (RF) applications such as user equipments or mobile phones, which have high RF transmission output power, the RF voltage swing can be higher than the maximum voltage that one single FET can handle. As illustrated in FIG. 3, a device 10 for switching RF signals includes two or more FETs 12, 14, 16, 18, etc., connected in a stack or chain topology in which the source (S) terminal of a FET is connected directly to the drain (D) terminal of an adjacent FET in the chain. In FIG. 3, further FETs in the chain between FETs 16 and 18 that are not shown for purposes of clarity are indicated by the ellipsis symbol (“ . . . ”). The gate node of each of FETs 12-18, etc., is connected to a gate bias network 20, which also receives a switch control signal as an input. In response to the switch control signal, the device 10 opens or closes a circuit between a first RF signal node (“RF1”). The first RF signal node is defined by the source node of the last FET 18 in the chain. A second RF signal node (“RF2”) is defined by the drain node of the first FET 12 in the chain. The device 10 is commonly referred to as a switch stack or FET stack. Some switch stack implementations use anti-series configurations of FETs in a stack. For example, for an even amount of FETs, the outside terminals may only include source(s) and drain(s). Exemplary source-drain anti-series configurations include 1) S-D, D-S, S-D, . . . , D-S, S-D configuration, and 2) D-S, S-D, D-S, . . . , S-D, D-S configuration.

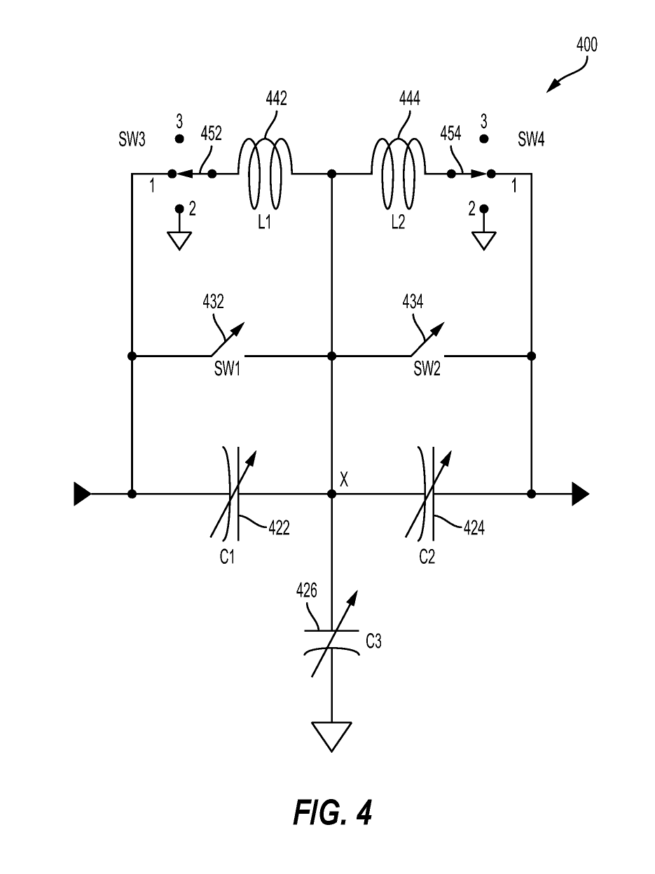

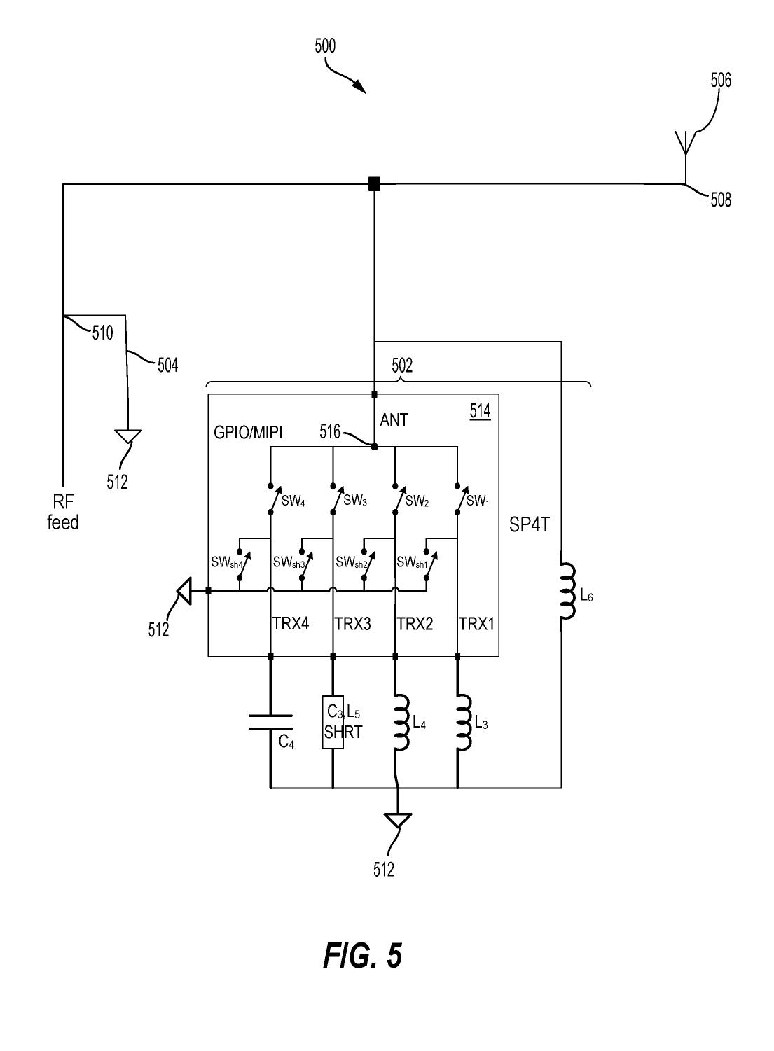

The switch stack may be implemented in a tuning circuit such as the impedance matching circuit of FIG. 4 or the aperture tuning circuit of FIG. 5.

FIG. 4 shows a schematic diagram of an exemplary design of an impedance matching circuit 400. Within the impedance matching circuit 400, a variable capacitor (varactor) 422 (C1) is coupled between an input of the impedance matching circuit 400 and a node X. A varactor 424 (C2) is coupled between the node X and an output of the impedance matching circuit 400. A varactor 426 (C3) is coupled between the node X and a circuit ground. A switch 432 (SW1) is coupled between the input of the impedance matching circuit 400 and the node X. A switch 434 (SW2) is coupled between the node X and the output of the impedance matching circuit 400. An inductor 442 (L1) is coupled between the node X and an input of a switch 452 (SW3). The switch 452 has a first output (‘1’) coupled to the input of the impedance matching circuit 400, a second output (‘2’) coupled to the circuit ground, and a floating third output (‘3’) that is not coupled to any circuit element. An inductor 444 (L2) is coupled between the node X and an input of a switch 454 (SW4). The switch 454 has a first output (‘1’) coupled to the output of the impedance matching circuit 400, a second output (‘2’) coupled to the circuit ground, and a floating third output (‘3’). The switch 452 may be implemented with (i) a first switch coupled between the inductor L1 and the input of the impedance matching circuit 400 and (ii) a second switch coupled between the inductor L1 and the circuit ground. The switch 454 may also be implemented with a pair of switches in a similar manner as switch 452. The switches SW1, SW2, SW3, and SW4 may be a switch stack or arranged in accordance with a switch stack.

The switches SW1 and SW2 may each be opened or closed (e.g., placed in one of two possible states). The switches SW3 and SW4 may each be controlled to connect the input to the first, second, or third output (e.g., placed in one of three possible states). The varactors C1, C2, and C3 may each be set to a minimum capacitance value to obtain a high impedance and essentially provide an open path. The varactors C1, C2, and C3 may have the same or different minimum capacitance values. The inductors 442 and 444 may each be coupled as a series element or a shunt element. The impedance matching circuit 400 may support a number of configurations. Each configuration is associated with a set of states/settings for the switches SW1, SW2, SW3, and SW4. Each configuration may also be associated with specific values for varactors C1, C2, and/or C3.

FIG. 5 shows a schematic diagram of an exemplary design of an aperture tuning circuit 500. The aperture tuning circuit 500 may include components such as inductors (e.g., L3, L4, L5 and L6), capacitors (e.g., C3 and C4), one or more switches (e.g., a switch stack), and/or other components that may be internal or external to the aperture tuning circuit 500. The aperture tuning portion 500 is coupled to an antenna terminal 508 associated with an antenna 506. The antenna terminal 508 is coupled to a transmission line via a terminal 510 that receives a radio frequency (RF) feed. The one or more switches may include an aperture tuning switch 514 such as a single pole four throw (SP4T) switch. For example, the SP4T switch includes a pole terminal 516 coupled to the antenna 506.

The SP4T switch also includes four throw portions represented by SW1, SW2, SW3 and SW4 that are respectively coupled to the inductor L3, the inductor L4, a parallel combination of the capacitor C3 and the inductor L5, and the capacitor C4 via respective terminals TRX1, TRX2, TRX3 and TRX4. The inductor L3, the inductor L4, a parallel combination of the capacitor C3 and the inductor L5, and the capacitor C4 are also tied to a ground terminal 512. The inductor is coupled to the pole terminal 516 and the ground terminal 512. The switch 514 may be a low loss switch to avoid degrading a radiating efficiency of the antenna 506. The SP4T aperture tuning switch 514 enables different antenna loadings to be selected, which produces shifts in antenna frequency response.

To suppress undesired resonance, shunt switches SWₛₕ₁, SWₛₕ₂, SWₛₕ₃ and SWₛₕ₄ are included in the aperture tuning switch 514. The shunt switches are respectively coupled to pole portions SW1, SW2, SW3 and SW4 and the ground terminal 512. For example, the shunt switches SWₛₕ₁, SWₛₕ₂, SWₛₕ₃ and/or SWₛₕ₄ may be ON and resistive when the aperture tuning switch 514 is off. Thus, due to the resistance of the shunt switches, the resonance mechanism is destroyed and undesired resonance removed.

Tuning circuits such as impedance matching circuits, aperture tuning circuits and AsDiv switch circuits are subject to high voltages. For example, tunable devices with tuning circuits generate very high harmonics (spurious emissions) and dissipate an increased power when radio frequency voltages become higher than the tuning circuit can handle. In addition, the tuning circuit is subject to hot-switching. Issues during hot-switching can occur when field effect transistors (FETs) latch and fail to switch with closed loop tuning under radio frequency (RF) power. For example, overvoltage of switches (e.g., used in impedance matching circuits and antenna aperture tuning circuits) leads to excessive harmonics radiation, heat loss, and tuning implementation failures.

These problems become pronounced for lower gate length technologies (e.g., used for scaling of future generations) in which voltage per field effect transistor is reduced. In other words, shrinking the technology nodes makes technology less suitable to cope with high voltages. Combined with the desire to support high RF voltages (e.g., in antenna aperture), the RF voltages could increase to 60-80V, due to a voltage gain factor of a high Q (quality) radiator.

Some implementations use impedance matching (IM) circuits while others use aperture tuning (AT) circuits and still others use a combination of both. Impedance matching improves tuner gain under “hand effects,” while aperture tuning (AT) is desirable in free-space. Aperture tuning adds frequency selectivity to improve match in specific frequency ranges depending on demands of the network. “Hand effects” may occur when the phone is grabbed on the antenna (e.g., covering the antenna).

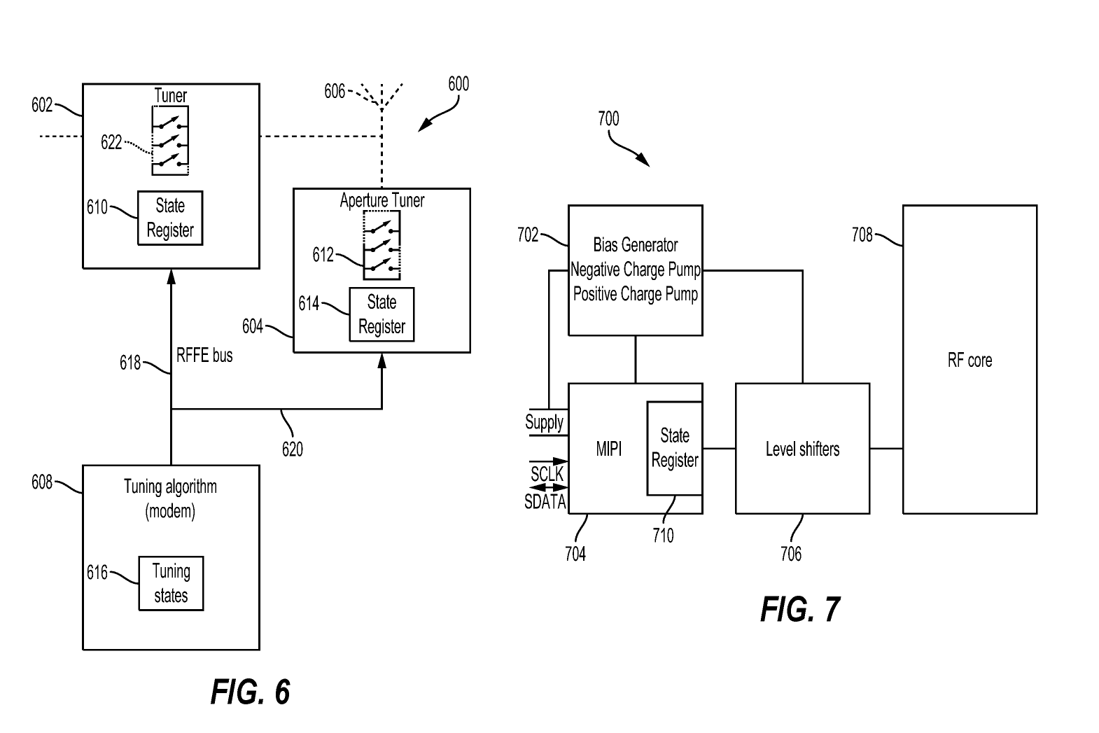

FIG. 6 illustrates an example of closed loop tuning system 600. The closed loop tuning system 600 includes a tuning circuit that has an impedance matching circuit 602 and/or an aperture tuning circuit 604. The impedance matching circuit 602 and the aperture tuning circuit 604 are coupled to an antenna 606 and an external tuning control device (e.g., a modem) 608. The impedance matching circuit 602 includes tunable/tuning components such as switches 622 (e.g., switch stack) and a state register 610. Similarly, the aperture tuning circuit 604 includes switches 612 and a state register 614. For example, the external tuning control device 608 selectively tunes an impedance value of variable impedance elements or components in the tuning circuit. The external tuning control device 608 interfaces with the tuning circuit via an interface device or control interface including a state register. The external tuning control device 608 reads state register information and applies this information to change the impedance of tuning components of the tuning device.

In both the impedance matching circuit 602 and the aperture tuning circuit 604, voltages across the tunable components (e.g., switch stack, etc.) can become increased without proper control or prediction in practice. To mitigate the increased voltage, the impedance matching circuit 602 and the aperture tuning circuit 604 are supported by a tuning implementation running in the external tuning control device 608. The tuning implementation may be achieved using look-up tables with (pre) selected tuning states 616. However, communication from the modem to the impedance matching circuit 602 and the aperture tuning circuit 604 may be one-directional, as illustrated by the arrows 618 and 620. This follows because modems, for example, are subject to mobile industry processor interface (MIPI) communications that are one directional with respect to overvoltage state information. For example, the modem transmits information to the impedance matching circuit 602 and the aperture tuning circuit 604 to set the tuning states. The tuning states are stored in state registers 610 and 614 of the impedance matching circuit 602 and the aperture tuning circuit 604. However, the impedance matching circuit 602 does not report overvoltage state information to the modem. The MIPI bus may be bi-directional with respect to other information such as device ID and revision.

FIG. 7 illustrates an example of a block schematic of a tuning device 700. For example, the tuning device 700 may be the impedance matching circuit 602 or the aperture tuning circuit 604. The tuning device 700 includes a bias generator 702, an interface device 704, level shifters 706 and a radio frequency core 708. The interface device 704 may be based on MIPI specifications. A state register 710 may be integrated in the interface device 704 or external but coupled to the interface device 704. The radio frequency core 708 may include the switch stack and other tuning components. The bias generator 702 is coupled to the interface device 704. The bias generator 702 and the interface device 704 are coupled to the radio frequency core 708 through the level shifters 706. The level shifters change voltage domains. A core of the interface device 704 based on MIPI specifications (e.g., MIPI core) and state registers (e.g., state register 710) operate on relatively low voltages (e.g., 1.8 to 1.2V). However, the radio frequency (RF) FETs specify relatively higher voltages such as −4V and +4V. Accordingly, level shifters change from the MIPI low voltage domain to the higher voltage domain of the RF FETs.

For example, the level shifters 706 perform logical switching “control” of the RF switch gates between positive charge pump voltage (ON) and negative charge pump voltage (OFF). An input of a level shifter is a common logic level signal referenced to ground, and an output is logically the same as the input signal, but swings between a positive charge pump level and a negative charge pump level. The positive charge pump level may be higher than the common logic supply level (or common logic level signal) and the negative charge pump level may be a negative voltage, below ground level.

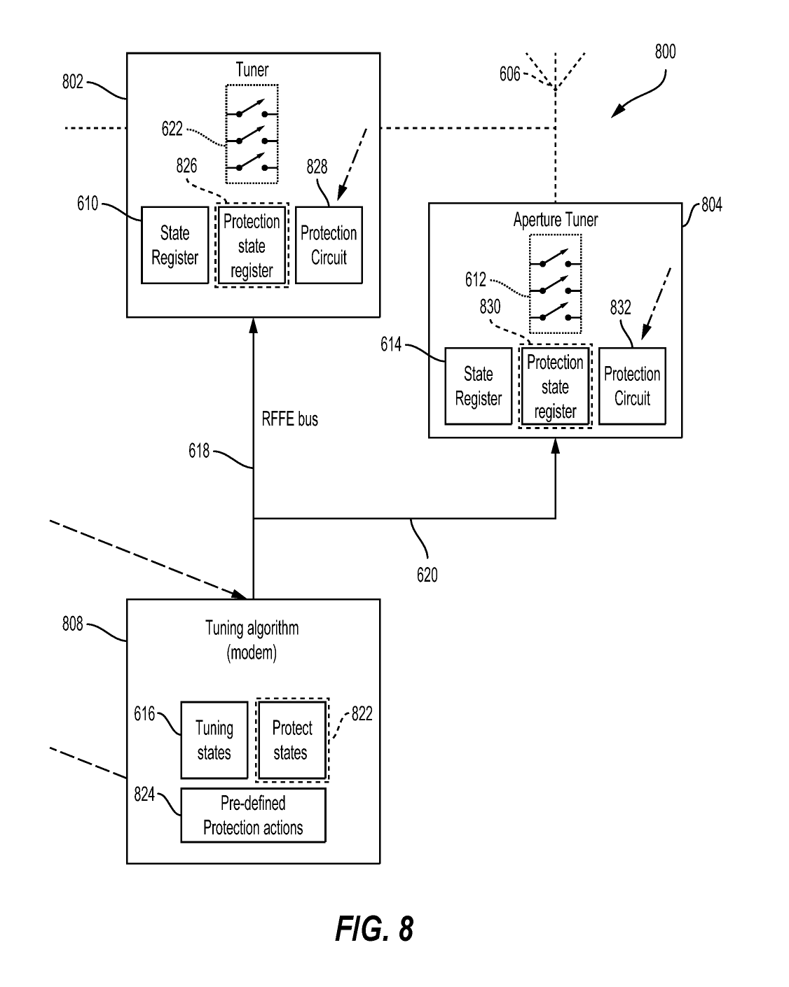

FIG. 8 illustrates another example of a closed loop tuning system 800 according to aspects of the present disclosure. For illustrative purposes, some of the labelling and numbering of the devices and features of FIG. 8 are similar to those of FIG. 6. An impedance matching circuit 802 and an aperture tuning circuit 804 of FIG. 8, however, respectively include protection circuits 828 and 832, and protection state registers 826 and 830 in addition to the state registers 610 and 614. The protection circuit may be an overvoltage protection circuit. The state registers store an additional state to set the tuner in safe state immediately after the protection circuit detects an issue. An external tuning control device 808 stores protection states 822 and pre-defined protection actions 824 in memory of the external tuning control device 808. The communications are two way. Thus, the external tuning control device 808 can provide instructions in response to receiving a state indication from the impedance matching circuit 802 and/or the aperture tuning circuit 804.

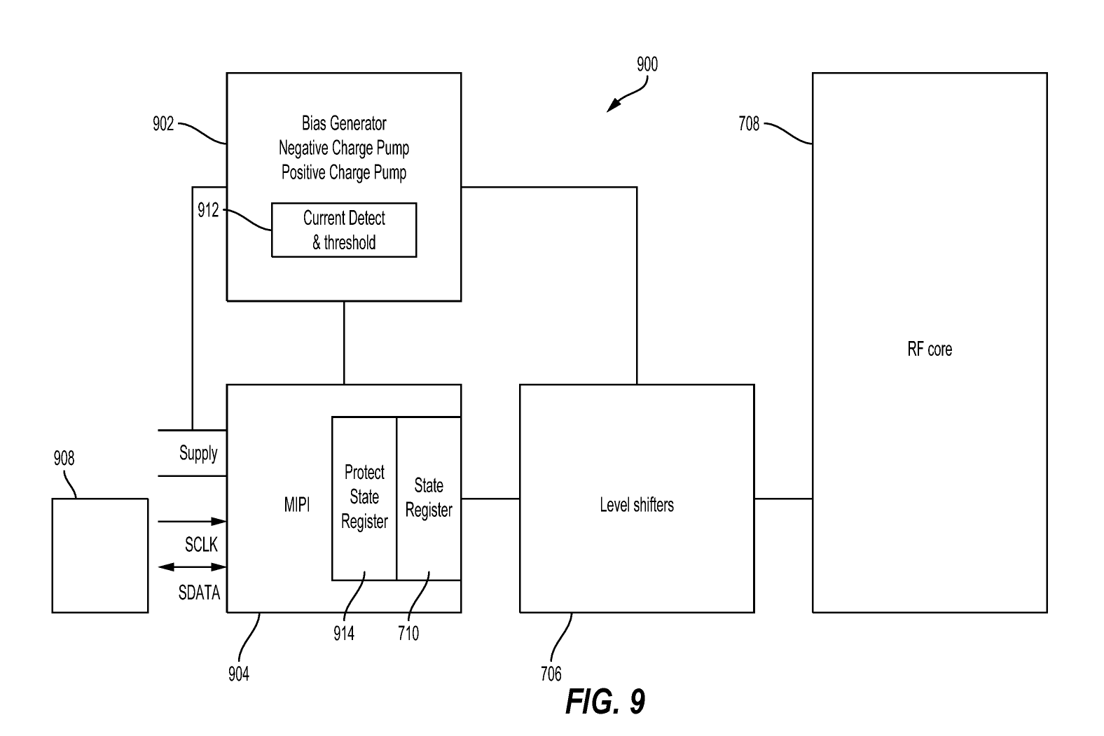

FIG. 9 illustrates another example of a block schematic of a tuning device 900 according to aspects of the present disclosure. For illustrative purposes, some of the labelling and numbering of the devices and features of FIG. 9 are similar to those of FIG. 7. A bias generator 902 of FIG. 9, however, includes a protection circuit. For example, the protection circuit can be a current detector and threshold device 912. The current detector and threshold device 912 may detect a charge pump current (e.g., radio frequency core bias current) and determine whether the charge pump current is above a threshold current value (or detect threshold). For example, the current detector and threshold device 912 may detect current supply associated with the negative charge pump or the positive charge pump. An interface device 904 based on MIPI specification includes a protection state register 914 in addition to the state register 610. The interface device 904 (e.g., a MIPI interrupt/polling device) is coupled to a modem 908. The interface device 904 and the bias generator receive power from a power source. The bias generator 902, the level shifter 706, and the interface device 904 are arranged in a control loop configuration.

In accordance with the closed loop configuration, the bias generator which may be the closed loop regulated charge pump (and provides positive and negative charge pumps), may monitor or detect two internal signals that may be proportional (linearly or non-linearly) to a supply current. For example, a main loop control voltage and a resulting controlled oscillator frequency of the control loop may be detected. In contrast, open loop configurations associated with open-loop regulated charge pump(s) achieve current sensing based on a total current of the charge pump. The open loop charge pump generates output voltage but no feedback.

The tuning states of the tuning device 900 can be controlled by the external tuning control device 908. The tuning states may include a list of protected states, which may be arranged in lookup tables and stored in memory (state register) of the external tuning control device 908. In one aspect of the disclosure, each time a state (e.g., normal state) is set in the tuning device 900, a protection state is set as well into the state registers to facilitate tuning the tuning device when the tuning device encounters the overvoltage or hot-switching condition. For example, when the radio frequency core bias current is above a programmable threshold, the protection registers can to set the radio frequency core 708 to a safe state.

In one aspect of the disclosure, the current detector and threshold device 912 may be a negative current detector (monitor) and programmable current threshold circuit. The programmable (supply) current threshold circuit detects undesirable harmonics. When the detected current is above a threshold current value, a protect state is in the radio frequency core 708. The protection circuit (e.g., overvoltage case detector) 828 or 832 indirectly monitors current drawn from radio frequency devices. For example, the protection circuit 828 or 832 detects DC current of a charge pump that correlates to an overvoltage condition based on comparison of the DC current to a threshold current value. Alternatively, the protection circuit 828 or 832 detects frequency of the control loop configuration instead of DC current.

The protection state register 914 may be included in the tuning device 900 to store another state (different from the normal state stored in the state register). The tuning device 900 may be set to the other state (a safe state) immediately after the current detector and threshold device 912 detects an overvoltage or hot-switching condition based on the threshold implementation. In other configurations, the tuning device is set to a safe state based on frequency band receiver readings.

In one aspect of the disclosure, a MIPI bus interrupt is sent to the external tuning control device 908 when a state change occurs in the tuning device 900. The interrupt is a signal to the external tuning control device 908 emitted by the tuning device 900 indicating an event that needs immediate attention. For example, the tuning device 900 reports (hot-switching/overvoltage condition) back to the external tuning control device 908 that runs the tuning process. The report may indicate that the tuning device 900 is operating in a safe state. The tuning device 900 sends the MIPI interrupt via the interface device 904. Accordingly, two-way communication exists between the tuning device 900 and the modem.

In one aspect of the present disclosure, positive and negative charge pumps of the bias generator 902 generate virtual supply rails (e.g., +4V, −4V respectively), which are greater than the chip supply voltages (e.g., 1.8V and 0V), which power the charge pumps and the digital portion of the chip 904. The closed-loop charge pumps maintain these output voltages over some specified range of output current loading. For example, the closed-loop charge pumps function as on-chip power supply. The level shifters 706 drive (or switch) either of these charge pump levels to the selected elements of the RF core 708 based on an ON or OFF command (e.g., chip's digital 1 or 0) from the MIPI state register 710. While there is commonly one level shifter for each RF core element, there is one set of charge pumps for all level shifters.

In some implementations, the RF core 708 presents a very high input impedance (e.g., capacitive) to the level shifter signals without drawing significant direct current (DC). Therefore, the charge pumps only supply charging current to the RF core inputs via the level shifters during the ON or OFF switching transients. During loading events, such as a switching transient, the closed-loop charge pumps self-correct to supply the transient charging currents while maintaining their designed output voltage levels. In some implementations, this self-correction to supply increased output current manifests as an increased voltage of a control signal from a normal, steady-state level, proportional to a specified increased output current. The increased control signal causes an increase in an oscillator frequency, which leads to increased charge pump output current. The increase in oscillator frequency further manifests as an increase in the 1.8V supply that powers the charge pumps. As the switching transient charges or discharges the RF core input, the load demand decays back to its very low steady-state value, and so does the control voltage, oscillator frequency, and supply current.

Overstress on the RF core devices correlates to the RF core devices drawing DC current on their input signals, thereby loading the charge pumps. The amount of input current increase correlates to the degree of overstress on the RF core 708. This unusual loading event is indicative of an overstress condition and may be detected either by observing a change from the steady-stage values of the charge pump control voltage, or of the resulting oscillator frequency change, or of the resulting increase in supply current.

Lower complexity, open-loop charge pump implementations do not actively regulate their output voltages, and do not have variable control signals or frequencies responding to loading changes. In these cases, it is difficult to detect overstress fault conditions by monitoring charge pump states.

Actions can be taken in accordance with the tuning implementation in the modem 908 in response to receiving the interrupt. For example, the actions include reducing output power or selecting a lower output power, selecting another antenna in accordance with antenna switch diversity (AsDIV), using another tuning state or implementing other options to move away from (undesired/unexpected) the overvoltage or hot-switching conditions. Some actions may be directed to the tuning device 900 (e.g., sending signals directly to the tuning device to change the state of the tuning device) while other actions may be indirect (e.g., sending signals to a power source to reduce an output power.)

Any overvoltage condition of gallium arsenide (GaAs), gallium nitride (GaN), silicon on insulator (SOI)) switches can be correlated to the DC domain supply current, and can be detected. Above a certain limit, a ‘safe-state’, or protection state, can be automatically set. Including the protection state register and protection circuit in the tuning device achieve a short response time for action when the tuning device is subject to the overvoltage condition or the hot-switching condition. After the safe state is automatically set at the tuning device based on the safe state stored in the protection state registers, a MIPI interrupt can be sent to the modem running the tuning implementation to take actions. Taking action at the modem, which is external to the tuning device, is subject to a longer response time. Aspects of the present disclosure are directed to a protection system where a safe state is stored locally in the tuning device, resulting in a fast response time. The protection system includes the processor (e.g., modem), tuning implementation running in the modem, and the interfacing (e.g., MIPI bus).

Aspects of the present disclosure address timing issues of a congested communication interface (e.g., MIPI bus) between the tuning circuit and the external tuning control device. The protection system achieves flexibility because the protection states can be pre-loaded in the tuning device, but are also stored in the phone memory (e.g. lookup table) such as memory of the external tuning control device.

Aspects of the present disclosure offer robust performance in closed loop tuning systems due to the addition of protection circuits in the tuning circuit and improve antenna performance of the user equipment (e.g., mobile phone). For example performance of the mobile phone is improved when subject to “hand effect” conditions. The protection system prevents spurious emissions or high-loss, which is particularly important for radio systems operating on an airplane or in airplane mode. Aspects of the present disclosure are applicable to impedance tuners, aperture tuners, switch banks/double pole double throw switches (e.g., 3x3 switches), etc.

In some aspects, switch technology of the tuning device (e.g., radio frequency core of the tuning device) includes metal oxide semiconductor field effect transistors (MOSFETs) that can be ON or OFF. For a certain switch (e.g., SW1, SW2, SW3, SW4, (of FIG. 3) which may be series switches) in a tuning device, the voltage across the switch can only become high if the switch is in an OFF state. The OFF state may be associated with certain impedance including certain inductance L or capacitance C. The switch is used to connect and disconnect power from a series load. The switch enables better power savings and safer operation. However, the series load switch inherently adds some impedance such as on-resistance (Ron). The combined effect of all the resistive components is referred to as the on-resistance. Adding too much resistance to a power path can lead to high power loss and large voltage drops. Using a load switch with low on-resistance counters these effects. However, selecting a device with an on-resistance that is too low causes an unnecessary increase in cost and size.

When the field effect transistor is in an overvoltage state, it is highly dissipative, which renders the ON state of the FETs undesirable. Despite the undesirability of the ON state under these conditions, it is better to turn ON the switch to operate in the ON state without generating high third order harmonics (H3) and without being highly dissipative. Turning ON the switch under these conditions reduces loss and reduces the third order harmonics.

In the protective state, input matching of the tuning device becomes less optimal. Therefore, an interrupt informs the modem running the tuning implementation that detected mismatch is caused by overvoltage protection to ensure rugged convergence of the tuning process. The modem then takes actions including lowering output power, or selecting another antenna in accordance with antenna switch diversity.

The tuning components may also include capacitors such as tunable series capacitors. A radio frequency voltage across a capacitor is inversely proportional to a capacitance value of the capacitor. A protection state may be given by a sum of the capacitance value and an offset (state+x), or a maximum capacitance. Define a C-value/state by a function that increases the C-value of the tunable capacitor if the binary state is increased (e.g. 5-bit array has states 0 to 31 (e.g., 32 states), but only 31 steps, and C-value from 1 pF to 8.75 pF). As voltage is proportional to capacitor impedance (Zc=1/wC), the voltage decreases for increasing C-values. Therefore, a protective state could be defined with a certain offset (x) from the used state or current state. For example, the capacitor state may be defined as ‘state’ and an associated protection state is defined as ‘state+x.’ Assume 1 pF C-value (state 0) gives an overvoltage ‘error’, and x=16, then the protective state=0+16=16 and associated C-value is 5 pF. In some implementations, for state x=16 to have a capacitance value of 5 pF, a maximum capacitance value is specified as 8.75 pF. Once the C-value is changed from 1 pF to 5 pF, the voltage drops (due to Zc=1/wC relationship), where w is the angular frequency.

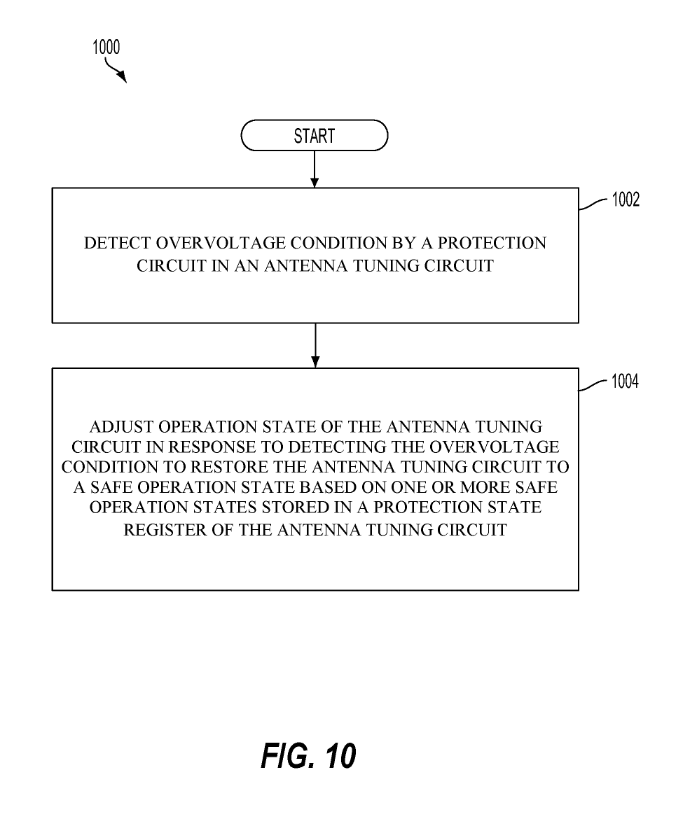

FIG. 10 depicts a simplified flowchart 1000 of a method for protecting an antenna tuning circuit or switch circuit according to one aspect of the disclosure. At block 1002, an overvoltage condition is detected by a protection circuit in the antenna tuning circuit. For example, detecting the overload condition includes receiving a charge pump current at the circuit and determining whether the charge pump current is above a threshold. Alternatively, detecting the overload condition includes receiving a frequency of a regulated charge pump output voltage control loop and detecting the overvoltage condition based on the frequency of the regulated charge pump output voltage control loop. The regulated charge pump output voltage control loop may include a charge pump and the circuit.

At block 1004, an operation state of the antenna tuning circuit is adjusted in response to detecting the overvoltage condition to restore the antenna tuning circuit to a safe operation state. The adjustment is based on one or more safe operation states stored in a protection state register of the antenna tuning circuit. For example, the external tuning control device pre-loads an operating state (tuning device setting) and a protection state in the tuning device. In one aspect, (negative) charge pump supply current detection above a programmable threshold triggers a protection state (safe state) in a short time-scale. The tuning device stays in the protection state until the modem releases the slave device into normal state.

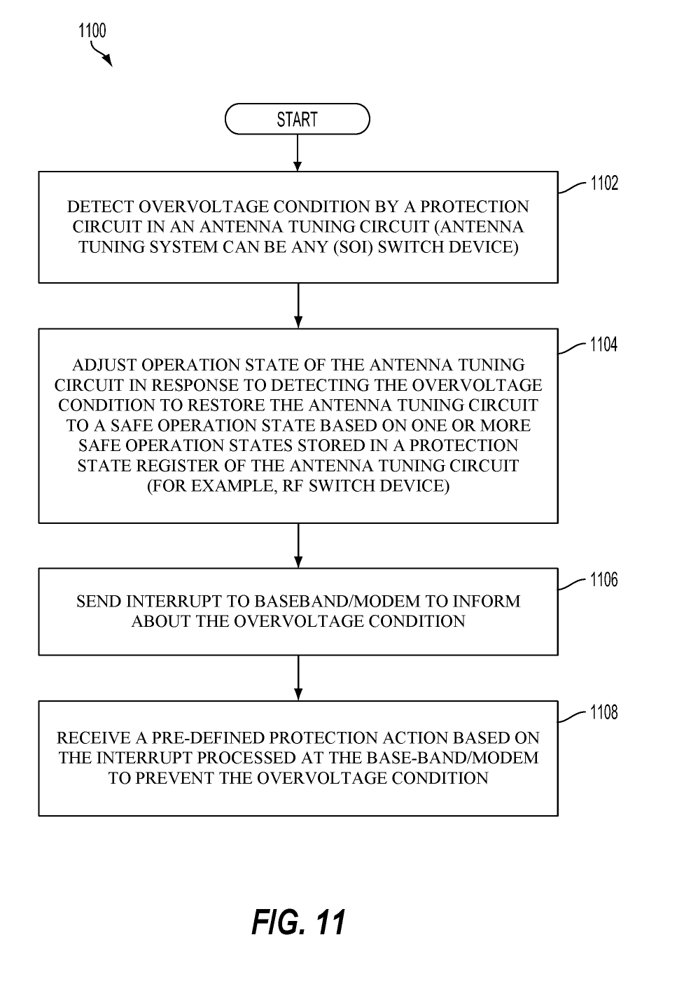

FIG. 11 depicts another simplified flowchart 1100 of a method for protecting an antenna tuning circuit or switch circuit according to one aspect of the disclosure. At block 1102, an overvoltage condition is detected by a protection circuit in the antenna tuning circuit. For example, the antenna tuning circuit may be any silicon-on-insulator (SOI) switch device or radio frequency switch device. At block 1104, an operation state of the antenna tuning circuit is adjusted in response to detecting the overvoltage condition to restore the antenna tuning circuit to a safe operation state. The adjustment is based on one or more safe operation states stored in a protection state register of the antenna tuning circuit. In some aspects, the protection states of the tuning circuit may be adjusted by adjusting switches in the tuning circuit and/or other tuning components such as a varactor.

At block 1106, an interrupt is sent to a baseband device/modem to provide information on the overvoltage condition. The interrupt may be an indication or parameter representative of the overvoltage condition. The interrupt (or signal via polling) reports back to the modem that the tuning device went into the protection state. For example, an indication (the interrupt) of the overvoltage condition is transmitted to the external tuning control device coupled to the circuit via an interrupt interface of the circuit. A process operating on the modem or baseband device incorporates the indication or parameter representative of the overvoltage condition to generate a response to the overvoltage condition. The tuning implementation running in the modem triggers one or more pre-defined protection actions to prevent or mitigate the overvoltage condition.

At block 1108, the antenna tuning circuit or switch circuit receives the response to the overvoltage condition (e.g., pre-defined protection action). For example, the baseband device or modem may send the pre-defined protection actions to the tuning circuit and/or other devices based on the processing of the parameter representative of the overvoltage condition at the modem or baseband device. In one aspect, the tuning circuit receives the pre-defined protection actions when the external tuning control device determines that the adjusted operation state fails to mitigate the overvoltage condition of the circuit.

The modem and corresponding tuning implementation running in the modem may be part of a tuner control block. The pre-defined protection action may include lowering power, use of another antenna (e.g., antenna switch diversity), or use of a different tuning state. The pre-defined protection action may include entering a new operation state such as a safe state or a less aggressive state.

According to a further aspect of the present disclosure, an antenna tuning system including an antenna tuning circuit or device is described. The antenna tuning device includes means for detecting an overload condition of the antenna tuning device. The overload condition detecting means may be the protection circuit 828, the protection circuit 832, the bias generator 902 and/or the current detector and threshold device 912. In another aspect, the aforementioned means may be any module, or any apparatus configured to perform the functions recited by the aforementioned means.

FIG. 12 is a block diagram showing an exemplary wireless communication system in which a configuration of the disclosure may be advantageously employed. For purposes of illustration, FIG. 12 shows three remote units 1220, 1230, and 1250 and two base stations 1240. It will be recognized that wireless communication systems may have many more remote units and base stations. Remote units 1220, 1230, and 1250 include IC devices 1225A, 1225C, and 1225B that include the disclosed antenna tuning system. It will be recognized that other devices may also include the disclosed antenna tuning system, such as the base stations, switching devices, and network equipment. FIG. 12 shows forward link signals 1280 from the base station 1240 to the remote units 1220, 1230, and 1250 and reverse link signals 1290 from the remote units 1220, 1230, and 1250 to base station 1240.

In FIG. 12, remote unit 1220 is shown as a mobile telephone, remote unit 1230 is shown as a portable computer, and remote unit 1250 is shown as a fixed location remote unit in a wireless local loop system. For example, a remote units may be a mobile phone, a hand-held personal communication systems (PCS) unit, a portable data unit such as a personal digital assistant (PDA), a GPS enabled device, a navigation device, a set top box, a music player, a video player, an entertainment unit, a fixed location data unit such as a meter reading equipment, or other communications device that stores or retrieve data or computer instructions, or combinations thereof. Although FIG. 12 illustrates remote units according to the aspects of the disclosure, the disclosure is not limited to these exemplary illustrated units. Aspects of the disclosure may be suitably employed in many devices, which include the antenna tuning system.

For a firmware and/or software implementation, the methodologies may be implemented with modules (e.g., procedures, functions, and so on) that perform the functions described herein. A machine-readable medium tangibly embodying instructions may be used in implementing the methodologies described herein. For example, software codes may be stored in a memory and executed by a processor unit. Memory may be implemented within the processor unit or external to the processor unit. As used herein, the term “memory” refers to types of long term, short term, volatile, nonvolatile, or other memory and is not to be limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include RAM, ROM, EEPROM, CD-ROM or other optical disk storage, magnetic disk storage or other magnetic storage devices, or other medium that can be used to store desired program code in the form of instructions or data structures and that can be accessed by a computer; disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

In addition to storage on computer-readable medium, instructions and/or data may be provided as signals on transmission media included in a communication apparatus. For example, a communication apparatus may include a transceiver having signals indicative of instructions and data. The instructions and data are configured to cause one or more processors to implement the functions outlined in the claims.

Although the present disclosure and its advantages have been described in detail, it should be understood that various changes, substitutions and alterations can be made herein without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above and below may refer to sides of a substrate or electronic device. Moreover, the scope of the present application is not intended to be limited to the particular configurations of the process, machine, manufacture, composition of matter, means, methods and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding configurations described herein may be utilized according to the present disclosure. Accordingly, the appended claims are intended to include within their scope such processes, machines, manufacture, compositions of matter, means, methods, or steps.

Those of skill would further appreciate that the various illustrative logical blocks, modules, circuits, and algorithm steps described in connection with the disclosure herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the disclosure herein may be implemented or performed with a general-purpose processor, a digital signal processor (DSP), an application specific integrated circuit (ASIC), a field programmable gate array (FPGA) or other programmable logic device, discrete gate or transistor logic device, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, multiple microprocessors, one or more microprocessors in conjunction with a DSP core, or any other such configuration.

The steps of a method or algorithm described in connection with the disclosure may be embodied directly in hardware, in a software module executed by a processor, or in a combination of the two. A software module may reside in RAM, flash memory, ROM, EPROM, EEPROM, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

In one or more exemplary designs, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a general-purpose or special-purpose computer. By way of example, and not limitation, such computer-readable media can include RAM, ROM, EEPROM, CD-ROM or other optical disk storage, magnetic disk storage or other magnetic storage devices, or any other medium that can be used to carry or store specified program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD) and Blu-ray disc where disks usually reproduce data magnetically, while discs reproduce data optically with lasers. Combinations of the above should also be included within the scope of computer-readable media.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover: a; b; c; a and b; a and c; b and c; and a, b and c. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112, sixth paragraph, unless the element is expressly recited using the phrase “means for” or, in the case of a method claim, the element is recited using the phrase “a step for.”

What is claimed is:

1. A circuit comprising:
a protection circuit to detect an overload condition based at least in part on a threshold value;
a protection state register coupled to the protection circuit to store at least one safe state of operation to which the circuit is restored in response to detecting the overload condition; and
a bus interface coupled to the protection state register to transmit an indication of a state of operation of the circuit to an external tuning control device coupled to the circuit and to receive pre-defined protection actions from the external tuning control device in response to the indication of the state of operation.

2. The circuit of claim 1, further comprising an impedance matching circuit, an antenna switch diversity circuit, radio frequency switches in a radio frequency front end module, a detuning circuit, and/or an aperture tuning circuit.

3. The circuit of claim 1, coupled to a charge pump to power the circuit, in which the protection circuit receives charge pump current from the charge pump and determines the overload condition based at least in part on whether the charge pump current is above the threshold value.

4. The circuit of claim 3, in which the overload condition is detected based at least in part on a steady-state value of a control voltage of the charge pump.

5. The circuit of claim 3, in which the overload condition is detected by the external tuning control device by detecting a second or third harmonic from non-linear signal detection.

6. The circuit of claim 1, in which the external tuning control device comprises a modem or a processor.

7. The circuit of claim 1, in which the external tuning control device comprises at least one state register to store at least one tuning state for the circuit, at least one protection state of the circuit, and the pre-defined protection actions.

8. The circuit of claim 1, in which the circuit is coupled to a charge pump to power the circuit in a control loop, in which a charge pump current from the charge pump is inferred by the protection circuit based on determining a frequency of the control loop.

9. The circuit of claim 1, in which the overload condition comprises overcurrent condition, overvoltage condition, or saturation leading to poor harmonic performance/high power dissipation condition.

10. A method for protecting a circuit comprising:
detecting an overload condition; and
adjusting an operation state of the circuit in response to detecting the overload condition to restore the circuit to a safe operation state based at least in part on at least one safe operation state stored in a protection state register of the circuit.

11. The method for protecting the circuit of claim 10, in which detecting the overload condition further comprises determining whether a charge pump current is above a threshold.

12. The method for protecting the circuit of claim 10, in which detecting the overload condition further comprises detecting the overload condition based at least in part on a frequency of a regulated charge pump output voltage control loop.

13. The method for protecting the circuit of claim 10, further comprising transmitting an indication of the overload condition to an external tuning control device coupled to the circuit via an interrupt interface.

14. The method for protecting the circuit of claim 13, further comprising receiving pre-defined protection actions from the external tuning control device in response to the indication.

15. The method for protecting the circuit of claim 14, in which the pre-defined protection actions from the external tuning control device include entering a new operation state including a safe state or a less aggressive state.

16. The method for protecting the circuit of claim 14, further comprising receiving the pre-defined protection actions when the external tuning control device determines that the adjusted operation state failed to mitigate the overload condition.

17. A circuit comprising:
means for detecting an overload condition of an antenna tuning device based at least in part on a threshold value;
a protection state register coupled to the overload condition detecting means to store at least one safe state of operation to which the circuit is restored in response to detecting the overload condition; and
a bus interface coupled to the protection state register to transmit an indication of a state of operation of the circuit to an external tuning control device coupled to the circuit and to receive pre-defined protection actions from the external tuning control device in response to the indication of the state of operation.

18. The circuit of claim 17, further comprising an impedance matching circuit, an antenna switch diversity circuit, radio frequency switches in a radio frequency front end module, a detuning circuit, and/or an aperture tuning circuit.

19. The circuit of claim 17, coupled to a charge pump to power the circuit, in which the overload condition detecting means includes means for receiving charge pump current from the charge pump and means for determining the overload condition based at least in part on whether the charge pump current is above the threshold value.

20. The circuit of claim 19, in which the overload condition detecting means detects based at least in part on a steady-state value of a control voltage of the charge pump.

21. The circuit of claim 17, in which the external tuning control device comprises at least one state register to store at least one tuning state for the circuit, at least one protection state of the circuit, and the pre-defined protection actions.

22. The circuit of claim 17, in which the circuit is coupled to a charge pump to power the circuit in a control loop, in which a charge pump current from the charge pump is inferred by the overload condition detecting means based at least in part on a determining a frequency of the control loop.

23. The circuit of claim 17, in which the overload condition is detected by the external tuning control device by detecting a second or third harmonic from non-linear signal detection.

24. The circuit of claim 17, in which the overload condition comprises an overcurrent condition, an overvoltage condition, or saturation leading to poor harmonic performance/high power dissipation condition.
